(19) United States
(12) Patent Application Publication
(10) Pub. No.: US 2006/0001068 A1
(43) Pub. Date: Jan. 5, 2006

(54) Multi-layer capacitor using dielectric layers having differing compositions

(76) Inventors: Larry E. Mosley, Santa Clara, CA (US); Juan Soto, Chandler, AZ (US); Nicholas Holmberg, Gilbert, AZ (US); Kevin Lenio, Chandler, AZ (US); Behrooz Mehr, San Jose, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/883,490

(22) Filed: Jun. 30, 2004

(51) Int. Cl. H01L 27/108

(52) U.S. Cl. 257/306

(57) ABSTRACT

The present disclosure describes an embodiment of an apparatus comprising a first dielectric layer having a first variation of capacitance with temperature, a second dielectric layer having a second variation of capacitance with temperature, the second variation of capacitance with temperature being different than the first variation of capacitance with temperature, and a conductive layer sandwiched between the first and second dielectric layers. Also described is an embodiment of a process comprising forming a first dielectric layer comprising a dielectric having a first composition, stacking a conductive layer on the first dielectric layer, and stacking a second dielectric layer on the conductive layer, the second dielectric layer having a second composition different than the first composition. Other embodiments are also described and claimed.

### TECHNICAL FIELD

Embodiments of the invention relate generally to capacitors and in particular, but not exclusively, to multi-layer capacitors including dielectric layers having different compositions.

### BACKGROUND

Multi-layer capacitors are used in many different types of power delivery applications, from computer motherboards and packages to automotive applications. Multi-Layer Ceramic Capacitors (MLCCs) are a widely-used type of multi-layer capacitor that includes several layers of a single ceramic dielectric material separated from each other by layers of a conductive material. In many applications it is necessary or desirable for capacitors to have a uniform capacitance over a wide temperature range that could cover −55° C. to 125° C., or even larger. A uniform capacitance simplifies application design because the temperature need not be taken into account, and also improves performance of the application. The capacitance C of MLCCs, however, exhibits a very strong capacitance variation with temperature because the capacitance of ceramic dielectric materials used in ceramic capacitors—or, more accurately, their dielectric constant ε—varies significantly with temperature. Thus, the capacitance of an MLCC is not constant with temperature, but rather is a function of temperature C(T).

To reduce the variation of an MLCC's capacitance with temperature, ceramic capacitor suppliers use dopants. The exact effect of the dopant depends on the particular dopant used and the amount of dopant mixed with the base dielectric, although two results are predominant. Some formulations result in smaller variation of capacitance with temperature, but with significant loss in capacitance because dopants substantially reduce the dielectric constant of the material. Other formulations maintain the high capacitance values and strong temperature dependence, but shift the temperature where the capacitance is a maximum.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1A is a perspective view of an embodiment of the invention comprising a multi-layer capacitor.

FIG. 1B is a perspective view of another embodiment of the invention comprising a multi-layer capacitor.

FIG. 2A is a perspective view of still another embodiment of the invention comprising a multi-layer capacitor.

FIG. 2B is a perspective views of yet another embodiment of the invention comprising a multi-layer capacitor.

FIG. 3 is a graph illustrating the variation of capacitance with temperature for an embodiment of the invention.

FIG. 4 is a side elevation of an embodiment of the invention comprising a multi-layer capacitor with attached terminals.

FIG. 5 is a schematic of an embodiment of a system including a multi-layer capacitor according to the present invention.

### DETAILED DESCRIPTION OF THE ILLUSTRATED EMBODIMENTS

Embodiments of a multi-layer capacitor including dielectric layers with different variations of capacitance with temperature are described herein. In the following description, numerous specific details are described to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in this specification do not necessarily all refer to the same embodiment. Furthermore, the particular features, structures, or characteristics may be combined in any suitable manner in one or more embodiments.

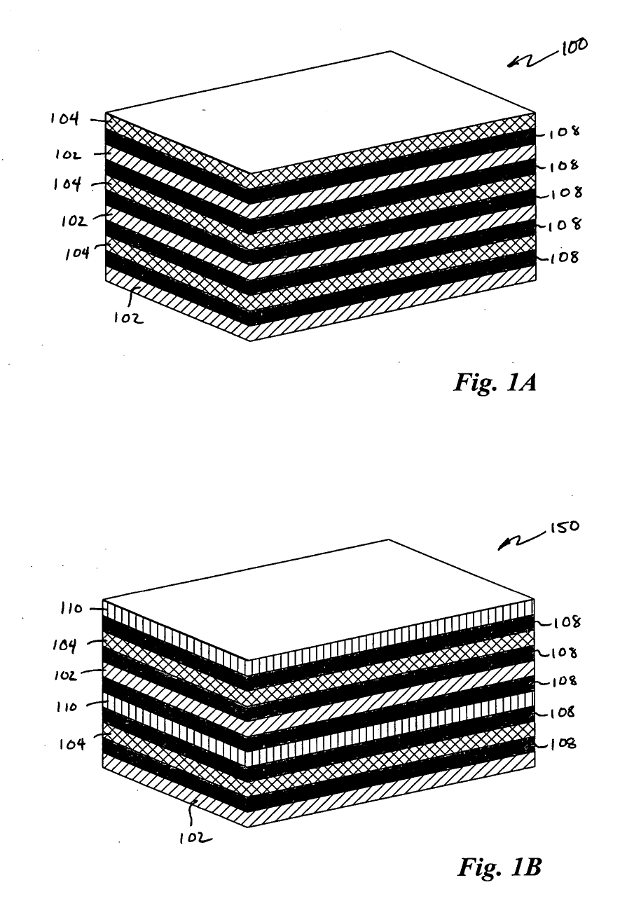

FIG. 1A illustrates an embodiment of the invention comprising a multi-layer capacitor 100. The capacitor 100 includes a stack of dielectric materials made up of alternating dielectric layers 102 having a first composition (referred to herein as a “first dielectric layers,” regardless of the number of layers present or their sequence) and dielectric layers 104 having a second composition (referred to herein as a “second dielectric layers,” regardless of the number of layers present or their sequence). The first dielectric layers 102 are separated from the second dielectric layers 104 by conductive layers 108 sandwiched between the dielectric layers.

Although the illustrated embodiment shows the conductive layers 108 with substantially the same thickness as the alternating dielectric layers 102 and 104, in other embodiments the conductive layers may be thinner or thicker than the dielectric layers. Similarly, in the illustrated embodiment the first dielectric layers 102 are shown with the same thickness as the second dielectric layers 104, but in other embodiments the first dielectric layers 102 may have greater or smaller thicknesses than the second dielectric layers 104. Finally, although in the illustrated embodiment the number of first dielectric layers 102 and second dielectric layers 104 is equal, in other embodiments there need not be equal numbers of first and second dielectric layers.

The conductive layers 108 sandwiched between each pair of first and second dielectric layers can be made of any kind of conductive material. In one embodiment, the conductive layers are made of a metal such as gold (Au), silver (Ag), aluminum (Al), nickel (Ni), platinum (Pt) or palladium (Pd), or alloys or combinations of these metals, such as palladium/silver (Pd/Ag). In other embodiments, other metals not listed and their combinations or alloys can be used. In still other embodiments, the conductive layers 108 can be made of conductive non-metals.

The first dielectric layers 102 and the second dielectric layers 104 are made of dielectric materials having different variations of capacitance with temperature and, therefore, different compositions. In other words, each first dielectric layer 102 will have a first composition, while each second dielectric layer 104 will have a second composition. The first composition will be different than the second composition, such that the first and second dielectric layers have different C(T) distributions. No particular composition is required for the dielectric layers 102 or 104, as long as the chosen compositions, when stacked together as shown, provide the desired C(T) distribution for the capacitor 100. In one embodiment, the first and second compositions may comprise the same base dielectric (e.g., Barium Titanate, BaTiO₃) but include different dopants, thus creating different compositions. For example, the first composition can include a base dielectric of Barium Titanate doped with zirconium (Zr), while the second composition can include the same Barium Titanate base dielectric doped with calcium (Ca) instead of zirconium. In other embodiments, the different first and second compositions can include the same base substrate, but with different concentrations of the same dopant or dopants; different base substrates, but with the same dopants; different base substrates with different dopants; or different base substrates with no dopants at all.

The capacitor 100 can be made in a variety of ways. In one embodiment of a process for making the capacitor, batches of the first and second compositions are prepared to create two separate slurries, one for each composition. The first slurry (i.e., the slurry of the first composition) includes solvents mixed with a base dielectric and any dopants, while the second slurry (i.e., the slurry of the second composition) similarly includes solvents mixed with a base dielectric and any dopants. The first slurry is spread into a layer on a sheet and allowed to dry. After the first slurry layer dries, a conductive layer is deposited on the first slurry layer, and then a second slurry layer (i.e., a layer of the second slurry) is deposited onto the conductive layer and also allowed to dry. Another conductive layer is deposited on the second slurry layer, and the process is repeated again until the desired number of layers has been stacked. The result is a sheet of many capacitors composed of stacked dielectric layers separated by conductive layers.

Once completed, the flexible sheet must cured, diced into individual capacitors and fired. Curing involves raising the temperature of the sheet to evaporate the slurry solvents. After curing, the sheet is “diced” into individual capacitors, which are then fired by heating to a high temperature; the exact temperature of firing will depend on the dielectric compositions used. Firing the capacitors hardens the dielectric layers and crystallizes grains in the dielectric layers, perfecting their dielectric properties.—After the individual capacitors have been fired, terminals are added to the exterior of the capacitor so that voltage can be applied to the internal conductive layers. The process described above for making the capacitor is only one potential process; in other embodiments, other processes having more, less, or different operations can be used.

FIG. 1B illustrates an alternative embodiment 150 of the multi-layer capacitor 100. The construction of the capacitor 150 is in most respects similar to the construction of the capacitor 100. The primary difference between the capacitor 150 and the capacitor 100 is in the number of different dielectric compositions employed. The capacitor 100 includes two different dielectric layers 102 and 104 with different C(T) distributions, while the capacitor 150 includes an additional dielectric layer 110, for a total of three different types of dielectric layer. The dielectric layer 110 can have a different composition—and therefore a different C(T)—than the first dielectric layer 102 and the second dielectric layer 104. The number of different dielectrics that can be used is not limited to two, as in the capacitor 100, or to three, as in the capacitor 150; in other embodiments of a capacitor, any number of dielectric layers with different C(T) distributions can be used. As with the capacitor 100, the capacitor 150 shows the conductive layers 108 with substantially the same thickness as the dielectric layers 102, 104 and 110. In other embodiments the conductive layers may be thinner or thicker than the dielectric layers. Similarly, in the illustrated capacitor 150 the first dielectric layers 102 are shown with the same thickness as the second dielectric layers 104 and third dielectric layers 110, but in other embodiments each of the first, second and third dielectric layers may have greater or smaller thicknesses than the others. Finally, although equal numbers of first dielectric layers 102, second dielectric layers 104 and third dielectric layers 110 are shown, in other embodiments the number of each type of layer present need not be equal.

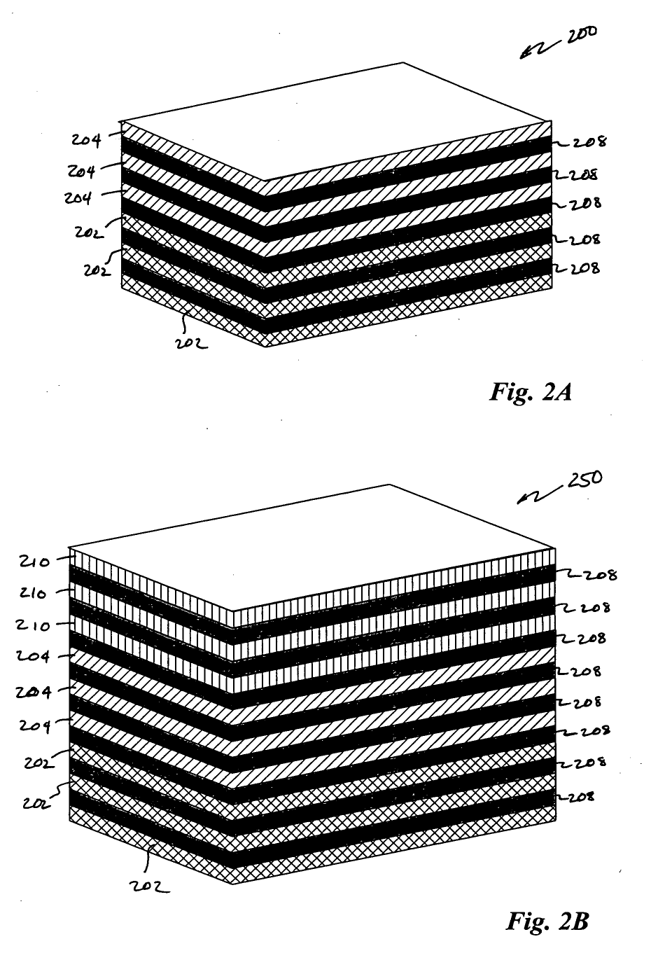

FIG. 2A illustrates an alternative embodiment of the invention comprising a multi-layer capacitor 200. As with the capacitor 100, the capacitor 200 includes a stack of dielectric materials made up of a set of first dielectric layers 202 and set of second dielectric layers 204. Within each set, the individual dielectric layers 202 or 204 are separated from each other by conductive layers 208, and the sets themselves are also separated by a conductive layer 208. The capacitor 200 differs from the capacitor 100 mainly in the arrangement of the first dielectric layers 202 and second dielectric layers 204: in the capacitor 100, the first and second dielectric layers alternate, whereas in the capacitor 200 the first dielectric layers 202 are grouped in a set of adjoining first dielectric layers and the second layers are similarly grouped into a set of adjoining second dielectric layers. The sets are then stacked, separated by a conductive layer. The proviso regarding the number of dielectric layers and their relative dimensions applies here: in other embodiments the conductive layers may be thinner or thicker than the dielectric layers, the first dielectric layers may have greater or smaller thicknesses than the second dielectric layers, and there need not be equal numbers of first and second dielectric layers.

FIG. 2B illustrates an alternative embodiment of the invention comprising a multi-layer capacitor 250. The construction of the capacitor 250 is in most respects similar to the construction of the capacitor 200. The primary difference between the capacitor 250 and the capacitor 200 is in the number of different dielectric layers employed. The capacitor 200 includes two different dielectric layers 202 and 204, each having a different C(T) distribution, while the capacitor 250 includes an additional dielectric layer 210, for a total of three different dielectric layers. The dielectric layer 210 can have a different composition—and therefore a different C(T)—than the first dielectric layer 202 and the second dielectric layer 204. The number of different dielectric layers that can be used is not limited to two, as in the capacitor 200, or to three, as in the capacitor 250. In other embodiments of a capacitor, any number of dielectric layers with different C(T) distributions can be used. The proviso regarding the number of dielectric layers and their relative dimensions applies here: in other embodiments the conductive layers may be thinner or thicker than the dielectric layers, each of the first, second and third dielectric layers may have greater or smaller thicknesses than the others, and the numbers of each type of layer present need not be equal.

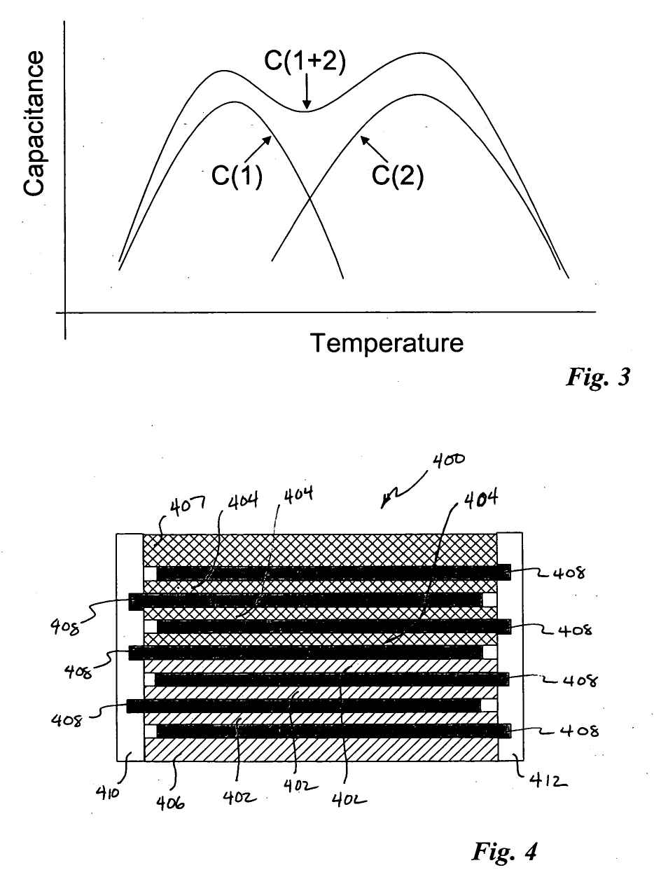

FIG. 3 graphically illustrates the variation of capacitance with temperature for multi-layer capacitor with two different dielectric layers, for example the previously-described capacitors 100 or 200, both of which include first dielectric layers and second dielectric layers with different C(T) distributions. In the graph, the curve labeled C(1) represents the variation with temperature of the capacitance of the first dielectric layer, while the curve C(2) represents the variation with temperature of the capacitance of the second dielectric layer. The curve labeled C(1+2) represents the variation with temperature of the capacitance of a capacitor combining both first and second dielectric layers. The curve C(1+2) shows that the combined dielectric layers have a capacitance level similar to the individual layers, while exhibiting less variation of capacitance with temperature over a broader range of temperatures than either curve C(1) or curve C(2) individually. The graph shown in the figure is easily extended to situations in which more than two dielectrics with different C(T) are used.

FIG. 4 illustrates an embodiment of a completed multi-layer capacitor 400. The basic construction of the capacitor 400 is similar to that of the previously-described capacitor 200: the capacitor 400 includes cover layers 406 and 407 between which are positioned a stack of dielectric materials. The cover layers 406 and 407 are positioned at the top and bottom of the stacked first and second dielectric layers 402 and 404. In the illustrated embodiment, the cover layer 406 has the same composition as the first dielectric layer 402 and the cover layer 407 has the same composition as the second dielectric layer. The primary difference between cover layers 406 and 407 and a dielectric layers 402 and 404 is the thickness: in some embodiments, the cover layers 406 and 407 will be thicker than the dielectric layers 402 and 404 for improved handling of the capacitor 400.

The dielectric materials stacked between the cover layers comprises a set of first dielectric layers 402 separated by conducting layers 408 and set of second dielectric layers 404 separated from each other by conductive layers 208. The first and second sets are also separated from each other by a conductive layer 208. The capacitor 400 includes a pair of terminals 410 and 412 on opposite sides of the exterior of the capacitor. The terminals 410 and 412 provide the means through which voltages can be applied to or more of the internal conductive layers 408. The terminals 410 and 412 are connected to alternating conductive layers 408; in other words, terminal 410 is connected to one conductive layer 408, terminal 412 to the next one in the stack, terminal 410 to the next, and so forth.

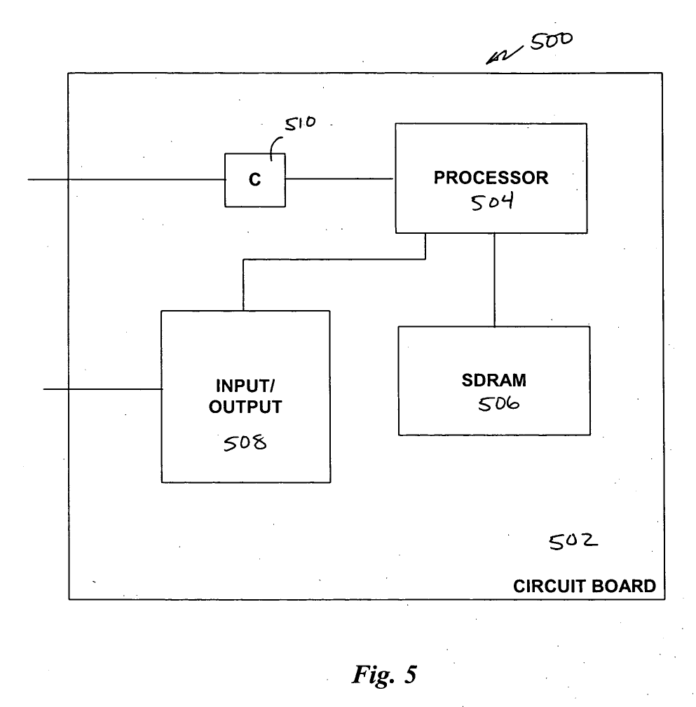

FIG. 5 illustrates an embodiment of a system 500 including an embodiment of a capacitor of the present invention. The system 500 includes a processor 504 mounted on and coupled to circuit board 502. A memory such as synchronous dynamic random access memory (SDRAM) 506 and an input/output interface 508 are both coupled to the processor. A capacitor 510 is coupled to the processor's power input. The capacitor 510 can be one of the previously described capacitors 100, 150, 200, 250, 400 or 450, or any other capacitor embodying the present invention.

The above description of illustrated embodiments of the invention, including what is described in the abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. An apparatus comprising:
a first dielectric layer having a first variation of capacitance with temperature;
a second dielectric layer having a second variation of capacitance with temperature, the second variation of capacitance with temperature being different than the first variation of capacitance with temperature; and
a conductive layer sandwiched between the first and second dielectric layers.

2. The apparatus of claim 1 wherein the first dielectric layer has a first composition and the second dielectric layer has a second composition, the first composition being different than the second composition.

3. The apparatus of claim 2 wherein the first composition comprises a first base dielectric having one or more dopants therein, and the second composition comprises a second dielectric having one or more dopants therein.

4. The apparatus of claim 2 wherein the first composition comprises a base dielectric having one or more dopants therein, and the second composition comprises the base dielectric having one or more dopants therein.

5. The apparatus of claim 2 wherein the first and second compositions are selected such that the apparatus has a substantially more constant capacitance over a its range of operating temperatures than the apparatus would have if all the layers were of the first composition or of the second composition.

6. The apparatus of claim 1 wherein the conductive layer comprises a metal.

7. The apparatus of claim 6 wherein the conductive layer comprises nickel (Ni), gold (Au), Silver (Ag), aluminum (Al), platinum (Pt), palladium (Pd) or combinations or alloys thereof.

8. The apparatus of claim 1, further comprising a terminal electrically coupled to the conductive layer.

9. An apparatus comprising:
a first dielectric set comprising a plurality of stacked dielectric layers separated from each other by conductive layers, each of the plurality of dielectric layers having a first composition;
a second dielectric set comprising a plurality of stacked dielectric layers separated from each other by conductive layers, each of the plurality of dielectric layers having a second composition different than the first composition; and
a conductive layer sandwiched between the first dielectric set and the second dielectric set.

10. The apparatus of claim 9 wherein the first composition has a first variation of capacitance with temperature and the second composition has a second variation of capacitance with temperature.

11. The apparatus of claim 9 wherein the first composition comprises a first base dielectric having one or more dopants therein, and the second composition comprises a second dielectric having one or more dopants therein.

12. The apparatus of claim 9 wherein the first composition comprises a base dielectric having one or more dopants therein, and the second composition comprises the base dielectric having one or more dopants therein.

13. The apparatus of claim 9 wherein the first and second compositions are selected such that the apparatus has a substantially more constant capacitance over a its range of operating temperatures than the apparatus would have if all the layers were of the first composition or of the second composition.

14. The apparatus of claim 9 wherein the conductive layers comprises a metal.

15. The apparatus of claim 14 wherein the conductive layer comprises nickel (Ni), gold (Au), Silver (Ag), aluminum (Al), platinum (Pt), palladium (Pd) or combinations or alloys thereof.

16. The apparatus of claim 9, further comprising a plurality of terminals electrically coupled to alternating conductive layers.

17. The apparatus of claim 9, further comprising:
a third dielectric set comprising a plurality of stacked dielectric layers separated from each other by conductive layers, each of the plurality of dielectric layers having a third composition different than the first composition and the second composition; and
a conductive layer sandwiched between the second dielectric set and the third dielectric set.

18. A process comprising:
forming a first dielectric layer comprising a dielectric having a first composition;
stacking a conductive layer on the first dielectric layer; and
stacking a second dielectric layer on the conductive layer, the second dielectric layer having a second composition different than the first composition.

19. The process of claim 18 wherein the first composition has a first variation of capacitance with temperature and the second composition has a second variation of capacitance with temperature.

20. The process of claim 18 wherein the first composition comprises a first base dielectric having one or more dopants therein, and the second composition comprises a second dielectric having one or more dopants therein.

21. The process of claim 18 wherein the first composition comprises a base dielectric having one or more dopants therein, and the second composition comprises the base dielectric having one or more dopants therein.

22. The process of claim 18, further comprising pressing together the first dielectric layer, the second dielectric layer and the conductive layer.

23. The process of claim 18, further comprising curing and firing the first and second dielectric layers.

24. A process comprising:
creating a first dielectric set comprising a plurality of stacked dielectric layers having conductive layers sandwiched therebetween, each of the plurality of dielectric layers having a first composition;
stacking a conductive layer on the first dielectric set; and
stacking a second dielectric set on the conductive layer, the second dielectric set comprising a plurality of stacked dielectric layers having conductive layers sandwiched therebetween, each of the plurality of dielectric layers having a second composition different than the first composition.

25. The process of claim 24 wherein the first composition has a first variation of capacitance with temperature and the second composition has a second variation of capacitance with temperature.

26. The process of claim 24 wherein the first composition comprises a first base dielectric having one or more dopants therein, and the second composition comprises a second dielectric having one or more dopants therein.

27. The process of claim 24 wherein the first composition comprises a base dielectric having one or more dopants therein, and the second composition comprises the base dielectric having one or more dopants therein.

28. The process of claim 24, further comprising pressing together the first dielectric layer, the second dielectric layer and the conductive layer.

29. The process of claim 24, further comprising curing and firing the first and second dielectric layers.

30. A system comprising:
a circuit board;
a processor coupled to the circuit board;
a SDRAM coupled to the processor; and
a capacitor connected to the processor, the capacitor comprising:
a first dielectric layer having a first variation of capacitance with temperature;
a second dielectric layer having a second variation of capacitance with temperature, the second variation of capacitance with temperature being different than the first variation of capacitance with temperature; and
a conductive layer sandwiched between the first and second dielectric layers.

31. The system of claim 30 wherein the first dielectric layer has a first composition and the second dielectric layer has a second composition, the first composition being different than the second composition.

32. The system of claim 31 wherein the first composition comprises a first base dielectric having one or more dopants therein, and the second composition comprises a second dielectric having one or more dopants therein.

33. The system of claim 31 wherein the first composition comprises a base dielectric having one or more dopants therein, and the second composition comprises the base dielectric having one or more dopants therein.

34. The system of claim 31 wherein the first and second compositions are selected such that the system has a substantially more constant capacitance over a its range of operating temperatures than the system would have if all the layers were of the first composition or of the second composition.
